(19) United States
(12) Patent Application Publication
(10) Pub. No.: US 2016/0366787 A1
(43) Pub. Date: Dec. 15, 2016

(54) LIQUID SUPPLY MECHANISM AND LIQUID COOLING SYSTEM

(71) Applicant: Cooler Master Co., Ltd., New Taipei City (TW)

(72) Inventors: Pen-Hung Liao, New Taipei City (TW); Shih-Wei Huang, New Taipei City (TW)

(21) Appl. No.: 14/736,273

(22) Filed: Jun. 11, 2015

(51) Int. Cl. H05K 7/20; B67D 7/36

(52) U.S. Cl. CPC H05K 7/20272; B67D 7/362

(57) ABSTRACT

A liquid supply mechanism includes a lower cover, an upper cover, a plunger and at least one resilient member. The lower cover has a liquid outlet and the upper cover is connected to the lower cover. A chamber is formed between the lower cover and the upper cover. The chamber communicates with the liquid outlet. The upper cover has a first magnetic area. The plunger is movably disposed in the chamber. The plunger has a second magnetic area and a position of the first magnetic area is corresponding to a position of the second magnetic area, such that a magnetic attraction force is generated between the first magnetic area and the second magnetic area. The resilient member is disposed in the chamber. Opposite ends of the resilient member abut against the upper cover and the plunger.

### BACKGROUND OF THE INVENTION

1. Field of the Invention

The invention relates to a liquid supply mechanism and a liquid cooling system and, more particularly, to a liquid supply mechanism capable of preventing a liquid cooling system from generating high hydraulic pressure while supplying a cooling liquid to the liquid cooling system.

2. Description of the Prior Art

In general, a liquid cooling system essentially consists of a liquid cooling head, a radiator, a pump and a liquid storage box connected through a plurality of tubes. When the liquid cooling system is dissipating heat from an electronic component, the pump transports a cooling liquid to the liquid cooling head, the cooling liquid absorbs the heat generated by the electronic component, and then the radiator cools the cooling liquid. After the liquid cooling system is used for a long time, the cooling liquid will reduce due to vaporization, such that the cooling liquid may be insufficient. If the user does not supply the cooling liquid in time, the liquid cooling system may be damaged due to insufficient cooling liquid.

### SUMMARY OF THE INVENTION

The invention provides a liquid supply mechanism and a liquid cooling system equipped with the liquid supply mechanism, so as to solve the aforesaid problems.

According to an embodiment of the invention, a liquid supply mechanism comprises a lower cover, an upper cover, a plunger and at least one resilient member. The lower cover has a liquid outlet and the upper cover is connected to the lower cover. A chamber is formed between the lower cover and the upper cover. The chamber communicates with the liquid outlet. The upper cover has a first magnetic area. The plunger is movably disposed in the chamber. The plunger has a second magnetic area and a position of the first magnetic area is corresponding to a position of the second magnetic area, such that a magnetic attraction force is generated between the first magnetic area and the second magnetic area. The resilient member is disposed in the chamber. Opposite ends of the resilient member abut against the upper cover and the plunger.

According to another embodiment of the invention, a liquid cooling system comprises a liquid cooling head, a radiator, a pump, a liquid storage box, a plurality of tubes and a liquid supply mechanism. The tubes are connected between the liquid cooling head, the radiator, the pump and the liquid storage box. The liquid supply mechanism is selectively connected to one of the liquid cooling head, the radiator, the pump, the liquid storage box and the tubes. The liquid supply mechanism comprises a lower cover, an upper cover, a plunger and at least one resilient member. The lower cover has a liquid outlet and the upper cover is connected to the lower cover. A chamber is formed between the lower cover and the upper cover. The chamber communicates with the liquid outlet. The upper cover has a first magnetic area. The plunger is movably disposed in the chamber. The plunger has a second magnetic area and a position of the first magnetic area is corresponding to a position of the second magnetic area, such that a magnetic attraction force is generated between the first magnetic area and the second magnetic area. The resilient member is disposed in the chamber. Opposite ends of the resilient member abut against the upper cover and the plunger.

As mentioned in the above, the liquid supply mechanism of the invention is selectively connected to one of the liquid cooling head, the radiator, the pump, the liquid storage box and the tubes. When the cooling liquid reduces and then the hydraulic pressure of the liquid cooling system reduces, the resilient member of the liquid supply mechanism will push the plunger to move, so as to inject the cooling liquid from the chamber into the liquid cooling system. In other words, the liquid supply mechanism of the invention can supply the cooling liquid to the liquid cooling system automatically when the cooling liquid is insufficient, so as to prevent the liquid cooling system from being damaged due to insufficient cooling liquid. Furthermore, when the plunger is moving, the magnetic attraction force generated between the first magnetic area of the upper cover and the second magnetic area of the plunger can reduce the push force generated by the resilient member for the plunger. Accordingly, the invention can prevent the liquid cooling system from generating high hydraulic pressure while supplying the cooling liquid to the liquid cooling system, such that the heat dissipating efficiency of the liquid cooling system will not be affected.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic view illustrating a liquid cooling system according to an embodiment of the invention.

FIG. 2 is a cross-sectional view illustrating a liquid supply mechanism and a radiator.

FIG. 3 is a cross-sectional view illustrating the plunger shown in FIG. 2 after moving.

### DETAILED DESCRIPTION

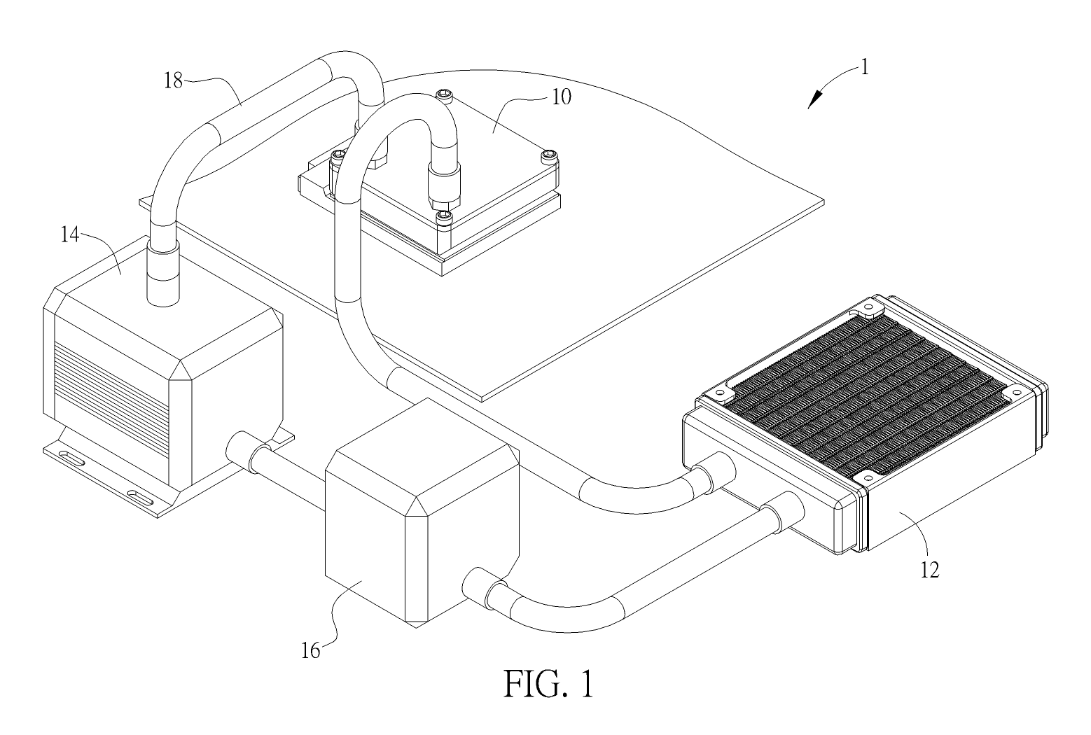

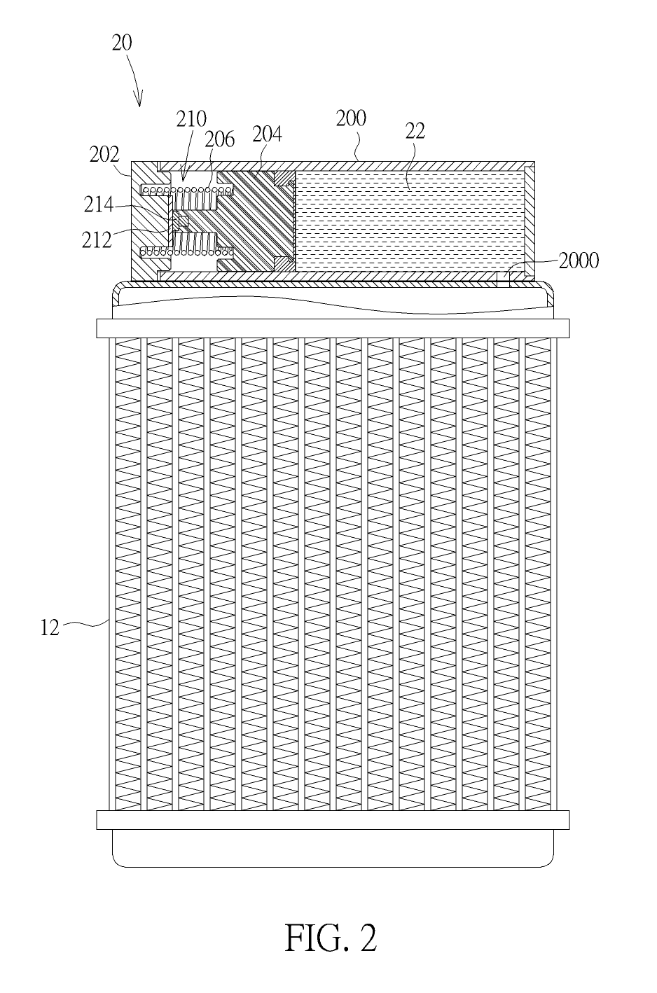

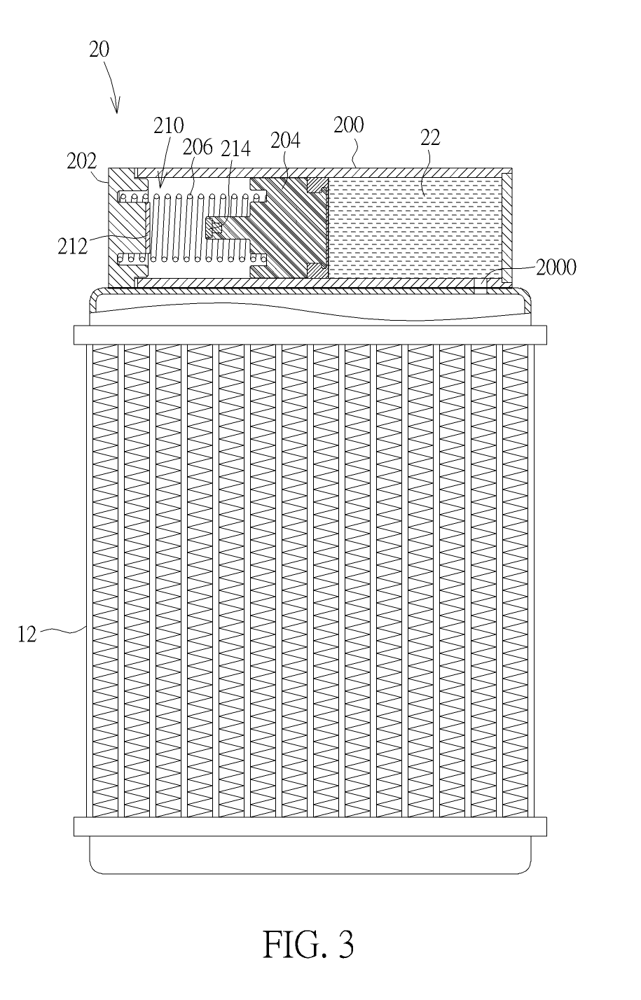

Referring to FIGS. 1 to 3, FIG. 1 is a schematic view illustrating a liquid cooling system 1 according to an embodiment of the invention, FIG. 2 is a cross-sectional view illustrating a liquid supply mechanism 20 and a radiator 12, and FIG. 3 is a cross-sectional view illustrating the plunger 204 shown in FIG. 2 after moving.

As shown in FIG. 1, the liquid cooling system 1 comprises a liquid cooling head 10, a radiator 12, a pump 14, a liquid storage box 16 and a plurality of tubes 18. The tubes 18 are connected between the liquid cooling head 10, the radiator 12, the pump 14 and the liquid storage box 16 and used for transporting a cooling liquid between the liquid cooling head 10, the radiator 12, the pump 14 and the liquid storage box 16. The cooling liquid (not shown in FIG. 1) is filled in the liquid cooling head 10, the radiator 12, the pump 14, the liquid storage box 16 and the tubes 18. When the liquid cooling system 1 of the invention is used for dissipating heat from an electronic component (not shown), the liquid cooling head 10 of the liquid cooling system 1 is attached on the electronic component. The pump 14 transports the cooling liquid to the liquid cooling head 10, the cooling liquid absorbs the heat generated by the electronic component, and then the radiator 12 cools the cooling liquid. In practical applications, the cooling liquid may be water or other liquids.

As shown in FIGS. 2 and 3, the liquid cooling system 1 further comprises a liquid supply mechanism 20 connected to the radiator 12. It should be noted that the liquid supply mechanism 20 is not limited to be connected to the radiator 12. In another embodiment, the liquid supply mechanism 20 may also be connected to the liquid cooling head 10, the radiator 12, the liquid storage box 16 or the tube 18. In other words, the liquid supply mechanism 20 of the invention may be selectively connected to one of the liquid cooling head 10, the radiator 12, the pump 14, the liquid storage box 16 and the tubes 18 according to practical applications.

The liquid supply mechanism 20 comprises a lower cover 200, an upper cover 202, a plunger 204 and at least one resilient member 206. The lower cover 200 has a liquid outlet 2000. The upper cover 202 is connected to the lower cover 200 and a chamber 210 is formed between the lower cover 200 and the upper cover 202. The chamber 210 communicates with the liquid outlet 2000 and contains a cooling liquid 22. The upper cover 202 has a first magnetic area 212. The plunger 204 is movably disposed in the chamber 210. The plunger 204 has a second magnetic area 214. In this embodiment, a position of the first magnetic area 212 is corresponding to a position of the second magnetic area 214, such that a magnetic attraction force is generated between the first magnetic area 212 and the second magnetic area 214. In practical applications, one of the first magnetic area 212 and the second magnetic area 214 may be a magnetic object (e.g. magnet, electromagnet, etc.) and the other one of the first magnetic area 212 and the second magnetic area 214 may be a magnetic object (e.g. magnet, electromagnet, etc.) or a magnetic induction material (e.g. iron or other metals). The resilient member 206 is disposed in the chamber 210. Opposite ends of the resilient member 206 abut against the upper cover 202 and the plunger 204. It should be noted that the number of the resilient members 206 may be determined according to practical applications, so the invention is not limited to the embodiment shown in the figures.

In this embodiment, the lower cover 200 of the liquid supply mechanism 20 is connected to the radiator 12, such that the liquid outlet 2000 communicates with the radiator 12.

As shown in FIGS. 2 and 3, when the liquid supply mechanism 20 is assembled completely and the chamber 210 contains the cooling liquid 22, the resilient member 206 is compressed. At this time, the resilient member 206 pushes the plunger 204 to move in the chamber 210 till the hydraulic pressure of the radiator 12 balances. When the cooling liquid of the radiator 12 reduces and then the hydraulic pressure reduces, the resilient member 206 of the liquid supply mechanism 20 will push the plunger 204 to move, so as to inject the cooling liquid 22 from the chamber 210 into the radiator 12. In other words, the liquid supply mechanism 20 of the invention can supply the cooling liquid to the liquid cooling system 1 automatically when the cooling liquid is insufficient, so as to prevent the liquid cooling system 1 from being damaged due to insufficient cooling liquid. It should be noted that in addition to the resilient member 206, the invention may also replace the resilient member 206 by other mechanisms, which may generate normal force, shearing force, torque or magnetic force, to push the plunger 204 to move, so as to supply the cooling liquid.

When the cooling liquid of the radiator 12 reduces and then the hydraulic pressure reduces, the resilient member 206 of the liquid supply mechanism 20 will push the plunger 204 to move, so as to inject the cooling liquid 22 from the chamber 210 into the radiator 12. When the plunger 204 is moving, the magnetic attraction force generated between the first magnetic area 212 and the second magnetic area 214 can reduce the push force generated by the resilient member 206 for the plunger 204. As shown in FIG. 2, when the chamber 210 contains more cooling liquid 22, the resilient member 206 has larger amount of compression, and the first magnetic area 212 and the second magnetic area 214 are close to each other. At this time, the magnetic attraction force generated between the first magnetic area 212 and the second magnetic area 214 is larger. In other words, when the chamber 210 contains more cooling liquid 22, the push force generated by the resilient member 206 for the plunger 204 is larger and the invention uses larger magnetic attraction force to provide larger damping effect, so as to reduce the push force generated by the resilient member 206 for the plunger 204. As shown in FIG. 3, when the chamber 210 contains less cooling liquid 22, the resilient member 206 has smaller amount of compression, and the first magnetic area 212 and the second magnetic area 214 are far away from each other. At this time, the magnetic attraction force generated between the first magnetic area 212 and the second magnetic area 214 reduces. In other words, when the chamber 210 contains less cooling liquid 22, the push force generated by the resilient member 206 for the plunger 204 reduces and the invention uses smaller magnetic attraction force to provide smaller damping effect, so as to reduce the push force generated by the resilient member 206 for the plunger 204. Accordingly, the invention can adjust the damping effect according to the amount of the cooling liquid 22 within the chamber 210, so as to prevent the liquid cooling system 1 from generating high hydraulic pressure while supplying the cooling liquid to the liquid cooling system 1, such that the heat dissipating efficiency of the liquid cooling system 1 will not be affected.

As mentioned in the above, the liquid supply mechanism of the invention is selectively connected to one of the liquid cooling head, the radiator, the pump, the liquid storage box and the tubes. When the cooling liquid reduces and then the hydraulic pressure of the liquid cooling system reduces, the resilient member of the liquid supply mechanism will push the plunger to move, so as to inject the cooling liquid from the chamber into the liquid cooling system. In other words, the liquid supply mechanism of the invention can supply the cooling liquid to the liquid cooling system automatically when the cooling liquid is insufficient, so as to prevent the liquid cooling system from being damaged due to insufficient cooling liquid. Furthermore, when the plunger is moving, the magnetic attraction force generated between the first magnetic area of the upper cover and the second magnetic area of the plunger can reduce the push force generated by the resilient member for the plunger. Accordingly, the invention can prevent the liquid cooling system from generating high hydraulic pressure while supplying the cooling liquid to the liquid cooling system, such that the heat dissipating efficiency of the liquid cooling system will not be affected.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A liquid supply mechanism comprising:
a lower cover having a liquid outlet;
an upper cover connected to the lower cover, a chamber being formed between the lower cover and the upper cover, the chamber communicating with the liquid outlet, the upper cover having a first magnetic area;
a plunger movably disposed in the chamber, the plunger having a second magnetic area, a position of the first magnetic area being corresponding to a position of the second magnetic area, such that a magnetic attraction force is generated between the first magnetic area and the second magnetic area; and
at least one resilient member disposed in the chamber, opposite ends of the resilient member abutting against the upper cover and the plunger.

2. The liquid supply mechanism of claim 1, wherein one of the first magnetic area and the second magnetic area is a magnetic object and the other one of the first magnetic area and the second magnetic area is a magnetic object or a magnetic induction material.

3. A liquid cooling system comprising:
a liquid cooling head;
a radiator;
a pump;
a liquid storage box;
a plurality of tubes connected between the liquid cooling head, the radiator, the pump and the liquid storage box; and
a liquid supply mechanism selectively connected to one of the liquid cooling head, the radiator, the pump, the liquid storage box and the tubes, the liquid supply mechanism comprising:
a lower cover having a liquid outlet;
an upper cover connected to the lower cover, a chamber being formed between the lower cover and the upper cover, the chamber communicating with the liquid outlet, the upper cover having a first magnetic area;
a plunger movably disposed in the chamber, the plunger having a second magnetic area, a position of the first magnetic area being corresponding to a position of the second magnetic area, such that a magnetic attraction force is generated between the first magnetic area and the second magnetic area; and
at least one resilient member disposed in the chamber, opposite ends of the resilient member abutting against the upper cover and the plunger.

4. The liquid cooling system of claim 3, wherein one of the first magnetic area and the second magnetic area is a magnetic object and the other one of the first magnetic area and the second magnetic area is a magnetic object or a magnetic induction material.
